(19) United States
(12) Patent Application Publication
(10) Pub. No.: US 2025/0380493 A1
(43) Pub. Date: Dec. 11, 2025

(54) SEMICONDUCTOR DEVICE AND METHOD OF MANUFACTURING THE SAME

(71) Applicant: Renesas Electronics Corporation, Tokyo (JP)

(72) Inventors: Kenichi HISADA, Tokyo (JP); Takashi ISHIGAKI, Tokyo (JP)

(21) Appl. No.: 19/075,946

(22) Filed: Mar. 11, 2025

(30) Foreign Application Priority Data
Jun. 7, 2024 (JP) 2024-092796

(51) Int. Cl. H10D 84/80; H01L 21/265; H01L 21/311; H01L 21/324; H10D 62/10; H10D 62/832; H10D 84/01; H10D 89/60

(52) U.S. Cl. CPC H10D 84/811; H01L 21/26513; H01L 21/31144; H01L 21/324; H10D 62/124; H10D 62/8325; H10D 84/01; H10D 89/611

(57) ABSTRACT

A method of manufacturing a semiconductor device according to the present disclosure includes: stacking a WSi layer and a TEOS layer on a surface of a P-type polysilicon layer formed on an SiC substrate; patterning the stacked WSi layer and TEOS layer so as to leave a second stacked region corresponding to an anode of the temperature detection diode; performing a first mask process so that, on a surface of the p-type polysilicon layer, a first region corresponding to a cathode of the temperature detection diode is exposed; implanting n-type ions into the first region; performing a second mask process so that, on the surface of the p-type polysilicon layer, a formation region of the temperature detection diode is masked; and performing etching on an exposed polysilicon layer.

### CROSS-REFERENCE TO RELATED APPLICATIONS

The disclosure of Japanese Patent Application No. 2024-092796 filed on Jun. 7, 2024, including the specification, drawings and abstract is incorporated herein by reference in its entirety.

### BACKGROUND

The present disclosure relates to a semiconductor device and a method of manufacturing the same, and relates to a semiconductor device with a temperature detection diode capable of realizing cost reduction, and a method of manufacturing the same.

For a semiconductor device such as a power device comprising MOSFET (Metal Oxide Semiconductor Field Effect Transistor) used as a switching device, it is required to mount a temperature detection diode for detecting the temperature of MOSFET. The temperature detection diode can monitor the temperature of MOSFET based on the detection result of the temperature detection diode. In particular, in recent years, there has been a demand for forming a temperature detection diode in the vicinity of a planar MOSFET using SiC (silicon carbide).

A related art is disclosed in, for example, Patent Document 1. In patent Document 1, a semiconductor device comprising trench type MOSFET of SiC with a temperature detection diode for detecting the temperature of MOSFET and its manufacturing method are disclosed.

### PRIOR ART DOCUMENTS

### Patent Document

[Patent Document 1] Japanese Unexamined Publication Laid-Open No. 2020-191420

### SUMMARY

As described above, in recent years, there has been a demand for mounting a planar MOSFET using an SiC and a temperature detection diode that detects the temperature of MOSFET. However, there is a problem that the cost increases due to an increase in the mask processing at the time of manufacturing the semiconductor device. Other problems and novel features will be apparent from the description of the present specification and the accompanying drawings.

A method of manufacturing a semiconductor device according to the present disclosure includes forming a p-type polysilicon layer on an SiC substrate on which an impurity layer is formed; stacking a WSi layer and a TEOS layer on the polysilicon layer; patterning the stacked WSi layer and TEOS layer so as to leave at least a first stacked region corresponding to a gate of MOSFET and a second stacked region corresponding to an anode of a temperature detection diode; performing a first mask process so that, on a surface the p-type polysilicon layer, a first region corresponding to a cathode of the temperature detection diode is exposed; implanting n-type ions into the first region; performing a second mask process so that, on the surface of the p-type polysilicon layer, a formation region of the temperature detection diode is masked; performing etching on an exposed region of the p-type polysilicon layer; forming an interlayer insulating layer over the SiC substrate; and forming a contact hole in each of a region corresponding to a source of the MOSFET, a region corresponding to the gate of the MOSFET, a region corresponding to the anode of the temperature detection diode and a region corresponding to the cathode of the temperature detection diode.

A semiconductor device according to the present disclosure includes an SiC substrate on which an impurity layer is formed; a first stacked portion comprising a p-type first polysilicon layer and a first WSi layer which are stacked on the SiC substrate, the first stacked portion being used for a gate of MOSFET; a second stacked portion comprising a p-type second polysilicon layer and a second WSi layer which are stacked on the SiC substrate, the second stacked portion being used for an anode of a temperature detection diode; contact layer provided on the SiC substrate and corresponding to the first stacked portion, the contact layer being used for a source of the MOSFET; an n-type diffusion region formed in the second polysilicon layer, the n-type diffusion region being used for a cathode of the temperature detection diode.

The present disclosure can provide a semiconductor device with a temperature detection diode capable of realizing cost reduction, and a method of manufacturing the same.

### BRIEF DESCRIPTION OF THE DRAWINGS

FIG. 1 is a schematic cross-sectional view illustrating a part of a manufacturing process for explaining a method of manufacturing a semiconductor device according to a first embodiment.

FIG. 2 is a schematic cross-sectional view illustrating a part of a manufacturing process for explaining the method of manufacturing the semiconductor device according to the first embodiment.

FIG. 3 is a schematic cross-sectional view illustrating a part of a manufacturing process for explaining the method of manufacturing the semiconductor device according to the first embodiment.

FIG. 4 is a schematic cross-sectional view illustrating a part of a manufacturing process for explaining the method of manufacturing the semiconductor device according to the first embodiment.

FIG. 5 is a schematic cross-sectional view illustrating a part of a manufacturing process for explaining the method of manufacturing the semiconductor device according to the first embodiment.

FIG. 6 is a schematic cross-sectional view showing one of the manufacturing steps for explaining the manufacturing method of the semiconductor device of a comparative example.

FIG. 7 is a schematic cross-sectional view showing one of the manufacturing steps for explaining the manufacturing method of the semiconductor device of the comparative example.

FIG. 8 is a schematic cross-sectional view showing one of the manufacturing steps for explaining the manufacturing method of the semiconductor device of the comparative example.

FIG. 9 is a schematic cross-sectional view showing one of the manufacturing steps for explaining the manufacturing method of the semiconductor device of the comparative example.

### DETAILED DESCRIPTION

Hereinafter, embodiments will be described with reference to the drawings. It should be noted that, since the drawings are simplified, the technical scope of the embodiments should not be construed narrowly based on the description of the drawings. In addition, the same elements are denoted by the same reference numerals, and redundant description thereof will be omitted.

In the following embodiments, when necessary for convenience, the description will be divided into a plurality of sections or embodiments. However, unless otherwise specified, they are not related to each other, and one of them is related to a part or all of the other, an application, a detailed description, a supplementary description, and the like. In addition, in the following embodiments, when referring to the number of elements (including the number, numerical value, amount, range, and the like), the number is not limited to a specific number, and may be a specific number or more or less, unless otherwise specified or in principle clearly limited to a specific number.

Furthermore, in the following embodiments, the constituent elements (including operation steps and the like) are not necessarily indispensable unless otherwise specified or considered to be essential in principle. Similarly, in the following embodiments, when referring to shapes, positional relationships, and the like of components and the like, it is intended to include substantially similar or similar shapes and the like, unless otherwise specified or in principle considered to be obviously not the same. This also applies to the above-mentioned numbers and the like (including numbers, numerical values, amounts, ranges, and the like).

### Preliminary Review

Before describing a method of manufacturing the semiconductor device 1 including the temperature detection diode, a method of the manufacturing the semiconductor device 50 not including temperature detection diode will be described as a comparative example.

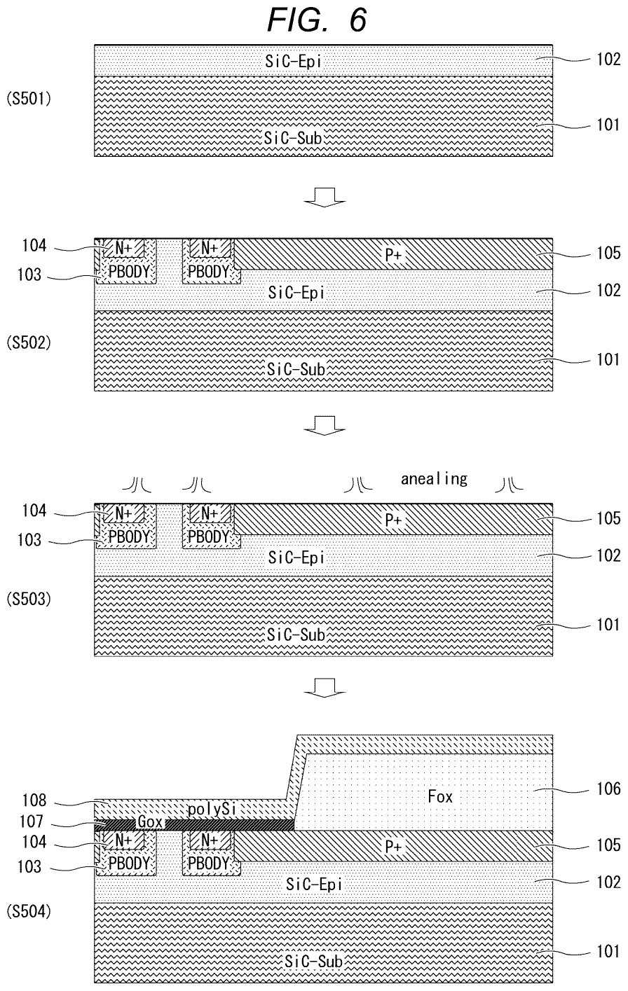

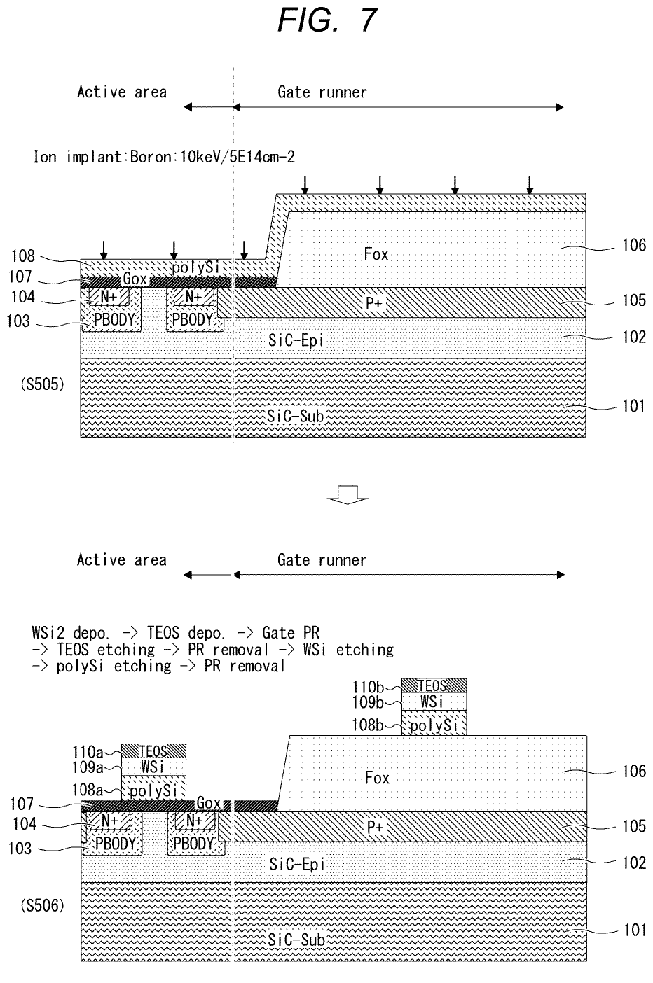

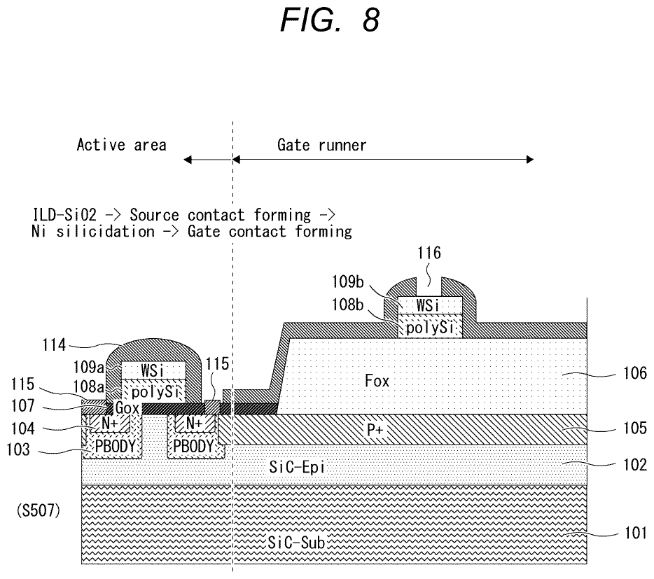

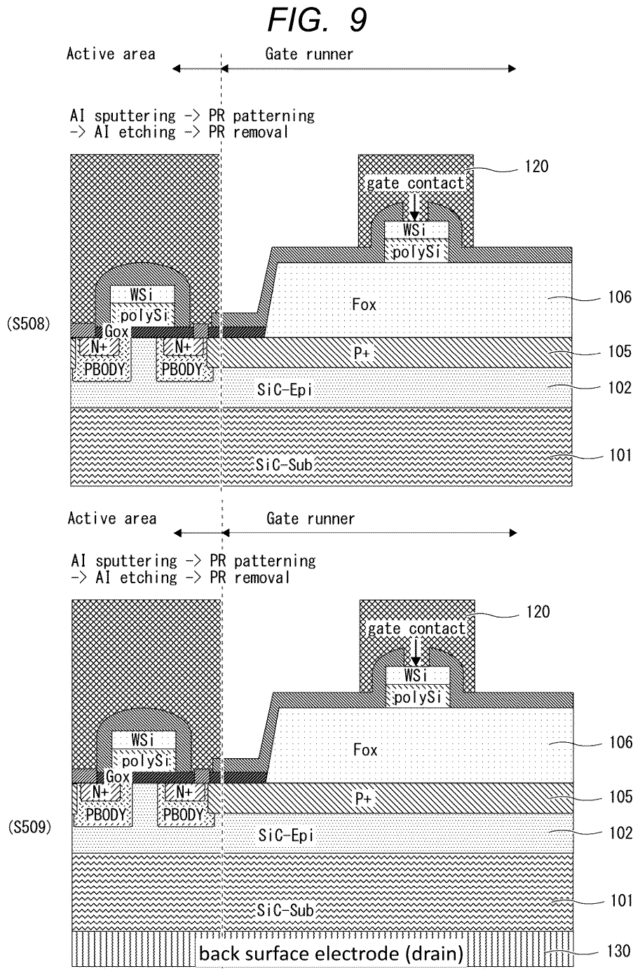

FIG. 6 to FIG. 9 are schematic cross-sectional views illustrating an example of each manufacturing step for explaining a manufacturing method of the semiconductor device 50 not equipped with the temperature detection diode. The semiconductor device 50 is, for example, a power device mounted on a vehicle, and includes at least a plurality of MOSFETs 10 used as switching devices, and a gate runner 30 that transmits a gate voltage to gate electrodes of the plurality of MOSFETs 10. The respective MOSFETs 10 are planar MOSFETs using SiC (silicon carbide). In FIG. 6 to FIG. 9, one of a plurality of MOSFETs 10 is illustrated.

First, in the step S501 process, an epitaxial layer (SiC-Epi) 102 is formed on SiC-Sub 101 of SiC. The thickness of the substrate 101 is, for example, about 350 um. An N-type impurity is introduced into the substrate 101 at a relatively high concentration, and the N-type impurity is, for example, nitrogen (N). The resistivity of the substrate 101 is, for example, about 20 mΩcm. The thickness of the epitaxial layer 102 is, for example, about 5 to 50 umt. The epitaxial layer 102 contains an N-type impurity, and the N-type impurity has approximately 1E15 to 5E16/cm\hat{ }3.

Thereafter, in the process of the step S502, impurity layers are formed in the epitaxial layer 102. Specifically, by repeating photolithography (patterning of photoresist), ion-implantation, and photoresist-removal a plurality of times, a set of two PBODYs (P-type layers) 103, a set of two N+ diffusion regions 104, and P+ diffusion region 105 are formed from the surface of the N-type epitaxial layer 102 to the inside. As the P-type ions, for example, ions of Al (aluminum) are used, and as the N-type ions, for example, ions of N (nitrogen) are used. PBODYs 103 and N+ diffused regions 104 are formed in the active region, which is a region where MOSFETS 10 are formed. The P+ diffusion region 105 is formed in the formation region of the temperature detection diode 20 and the formation region of the gate runner 30 provided between the active region and the formation region of the temperature detection diode 20.

As a process between the process of step S501 and the process of step S502, an alignment mark for photolithography may be formed on the surface of the epitaxial layer 102.

Further, in the process of step S502, at least one of SiO2 and polysilicon may be deposited on the epitaxial layers 102 prior to photolithography, and then photolithography may be performed. In this case, etching using a patterned photoresist as a mask is performed to form a hard mask made of at least one of patterned SiO2 and polysilicon. Thereafter, ion-implantation is performed using at least one of the patterned SiO2 and polysilicon as a hard mask. At this time, the ion implantation may be performed at a high temperature of 300 to 600° C.

Further, in the process of the step S502, a P-type layer having a higher concentration than PBODY 103 and a lower concentration than the P+ diffusion regions 105 may be formed below PBODY 103 in the epitaxial layer 102.

Thereafter, in the process of the step S503, the impurities formed in the epitaxial layer 102 are activated. Specifically, the surface of the epitaxial layer 102 is annealed at 1600 to 1800° C. for 1 to 60 minutes. Before annealing, a carbon film may be deposited on the wafer surface (the surface of the epitaxial layer 102) or on both surfaces (the surface of the epitaxial layer 102 and the back surface of the substrate 101), and then annealing may be performed. In this case, the carbon film is removed after annealing. In this material, SiC wafer is annealed at a higher temperature than the melting point of Si system compared to Si wafer. Therefore, SiC wafer needs to be annealed prior to depositing Si based materials such as field-oxide films, gate-oxide films, and polysilicon layers, which will be described later.

Thereafter, in the step S504 process, a field-oxide film (Fox), a gate-oxide film (Gox), and a polysilicon-layer (PolySi) are formed. Specifically, first, the field oxide film 106 is formed in the gate runner formation region and the temperature detection diode formation region (that is, in a region other than the active region). Thereafter, the gate oxide film 107 is formed in the active region by photolithography, oxide film etching, and gate oxidation. Thereafter, a non-doped polysilicon layer 108 is formed (deposited) on the respective surfaces of the field oxide film 106 and the gate oxide film 107. The thickness of the polysilicon layer 108 is, for example, about 200 nm.

Note that thermal oxidation may be performed before the field oxide film 106 is formed. In addition, in the gate oxidation, sacrificial oxidation and removal thereof may be performed. Before and after the gate-oxide, a process of modifying MOS interface (e.g., NO annealing) may be performed.

Thereafter, in the process of the step S505, the polysilicon layer 108 is ion-implanted. Specifically, B (boron) having a dose 5E14/cm\hat{ }2 is implanted into the polysilicon layer 108 at 10 keV energies. As a result, the polysilicon layer 108 is made P-type.

Thereafter, in the process of the step S506, a WSi (tungsten silicide) layer and a TEOS (tetraethoxysilane) layer are formed and each of the polysilicon layer, WSi layer, and TEOS layer is patterned. Specifically, first, a WSi layer 109 and a TEOS layer 110 are sequentially deposited on the surface of the polysilicon layer 108, and then photolithography (patterning of a photoresist) is performed on the surface of TEOS layer 110. Thereafter, TEOS layer 110, WSi layer 109, and the polysilicon layer 108 are etched using the patterned photoresist as a mask. After etching, the photoresist is removed. Note that the photoresist may be removed after etching TEOS layers 110 using the patterned photoresist as a mask and prior to etching WSi layer 109. In this process, WSi layer 109 and the polysilicon layer 108 are etched using the patterned TEOS layer 110 as a hard mask, and then the photoresists are removed.

Thus, in the active region, a stacked region (first stacked region) including the polysilicon layer 108a, WSi layer 109a and TEOS layer 110a is formed, and in the gate runner forming region, a stacked region (third stacked region) including the polysilicon layer 108b, WSi layer 109b and TEOS layer 110b is formed. The thickness of each of polysilicon-layers 108a and 108b is 200 nm as described above. The thickness of each of WSi layers 109a and 109b is, for example, about 250 nm. The thickness of each of TEOS layers 110a and 110b is, for example, about 200 nm.

Thereafter, in the process of the step S507, an interlayer insulating film (ILD; Inter Level Dielectric) of SiO2 is formed, a source contact is formed, and a gate contact is formed. Specifically, first, the interlayer insulating film 114 of SiO2 is formed so as to cover the wafer. Since TEOS layer 110 (110a and 110b) is included in the interlayer insulating film 114, they are omitted. Thereafter, in the active region, the contact hole 115 is formed on the upper surface of the N+ diffusion region 104 and so as to separate the stacked region of the polysilicon 108a and WSi layer 109a from the interlayer insulating film 114. Ni silicide is formed in the contact hole 115. For example, in forming Ni silicide, first annealing is performed on Ni (nickel) formed in the contact hole 115, and then second annealing is performed after the unreacted part of the annealing is removed. In addition, a contact hole 116 is formed in the gate runner formation region. Although not shown, a contact hole corresponding to the gate of MOSFET 10 may be formed.

For example, the contact hole 116 is formed on the upper surface of the stacked region of the polysilicon layer 108b and WSi layer 109b in the interlayer insulating film 114. The upper surface of the stacked region of the polysilicon layer 108b and WSi layer 109b is used as a gate contact of the gate runner 30. Although not shown, a contact hole may be formed in the upper surface of the stacked region of the polysilicon layer 108a and WSi layer 109a in the interlayer insulating film 114. The upper surface of the stacked region of the polysilicon layer 108a and WSi layer 109a is used as a gate contact of MOSFET 10. Thereafter, a TiW is deposited on the wafer. Annealing may be performed on the deposited TiW. In addition, TiW is not limited to being deposited, and Ti (titanium) and TiN (titanium nitride) may be laminated, or Ti and TiW may be laminated.

Then, in the step S508 process, a surface-electrode is formed. Specifically, first, Al is sputtered on the front face of the substrate. Then, photolithography is performed on the deposited Al layer 120. Thereafter, the deposited Al layer 120 and TiW (not shown) are etched using the patterned photoresist as a mask. As a result, the source electrode of MOSFET 10 and the gate electrode of the gate runner 30 connected to the gate electrode of MOSFET 10 are formed. After etching, the photoresist is removed. Although not shown, a passivation film covering the end portions of the source electrode and the gate electrode may be formed. The passivation film is formed of, for example, a SiN (silicon nitride) film or a polyimide film, and the passivation film is etched using a photoresist patterned by photolithography as a mask. After etching, the photoresist is removed.

After that, in the process of the step S509, the back surface is formed. Specifically, first, Ni is sputtered on the back surface of the substrate. Thereafter, laser annealing is performed on the deposited Ni layer to form Ni silicide. As a result, the back surface electrode 130 is formed on the back surface of the substrate.

Note that the back surface of the substrate 101 may be ground and thinned before the back surface electrode 130 is formed. In addition, the back surface 130 is not limited to being formed by Ni silicide, and may be formed by a stacked Ti, Ni, Ag, Au.

### First Embodiment

Next, a method of manufacturing the semiconductor device 1 according to the first embodiment in which the temperature detection diode is mounted will be described.

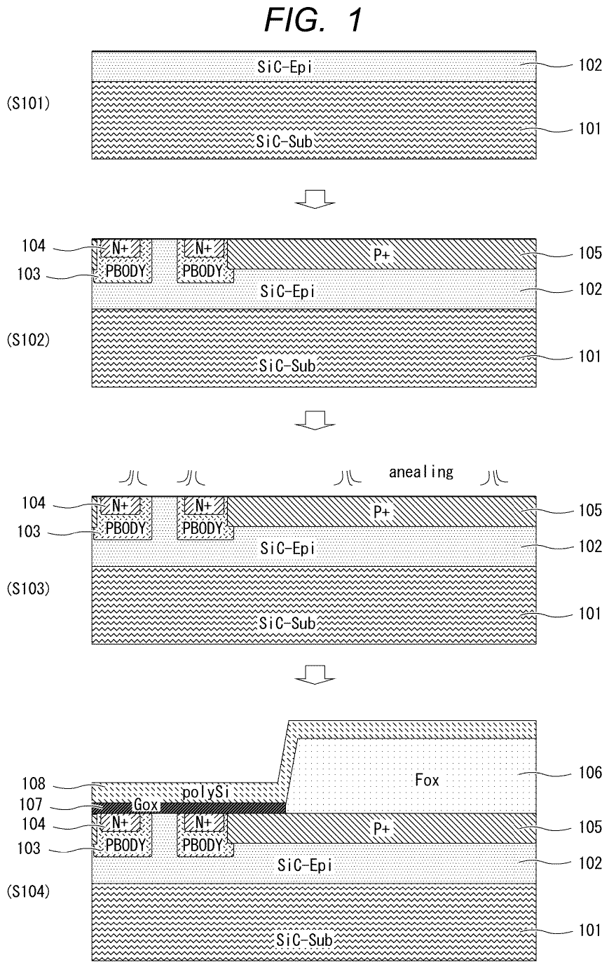

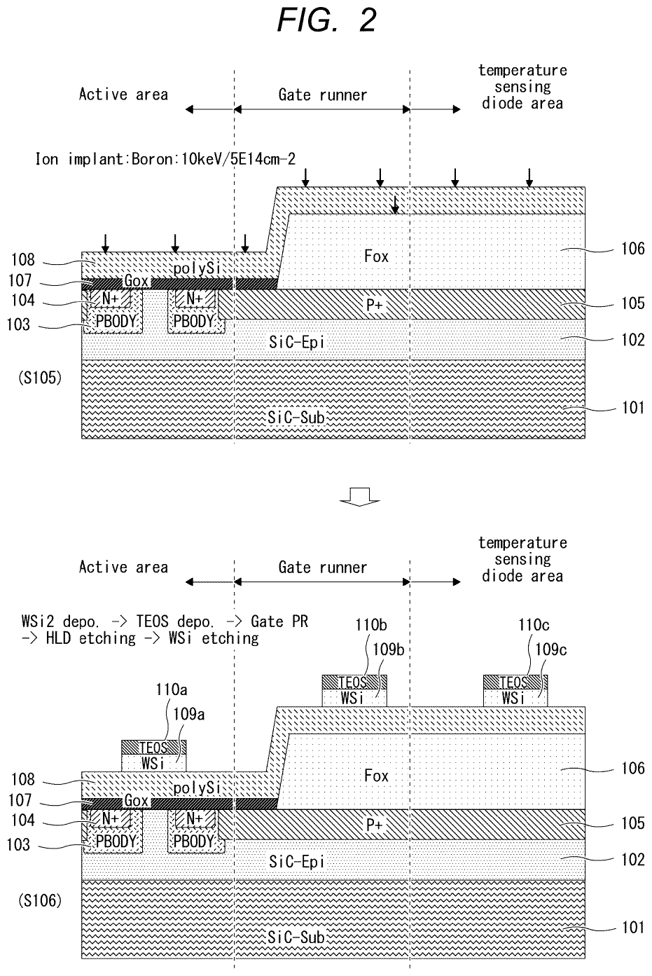

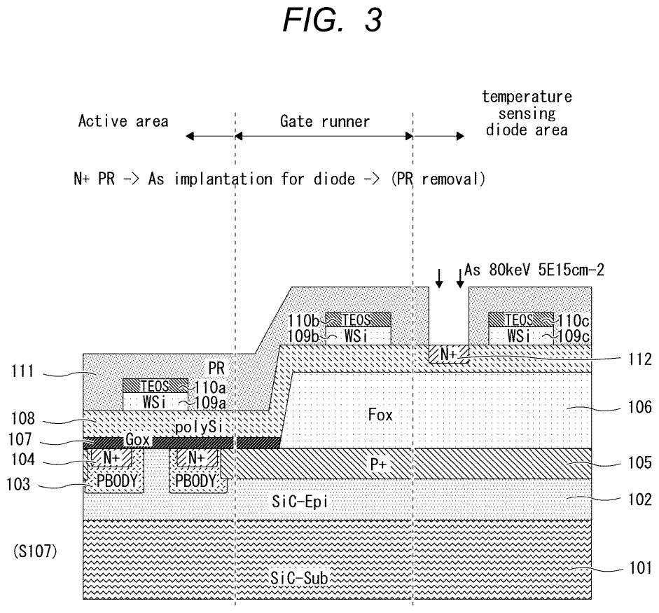

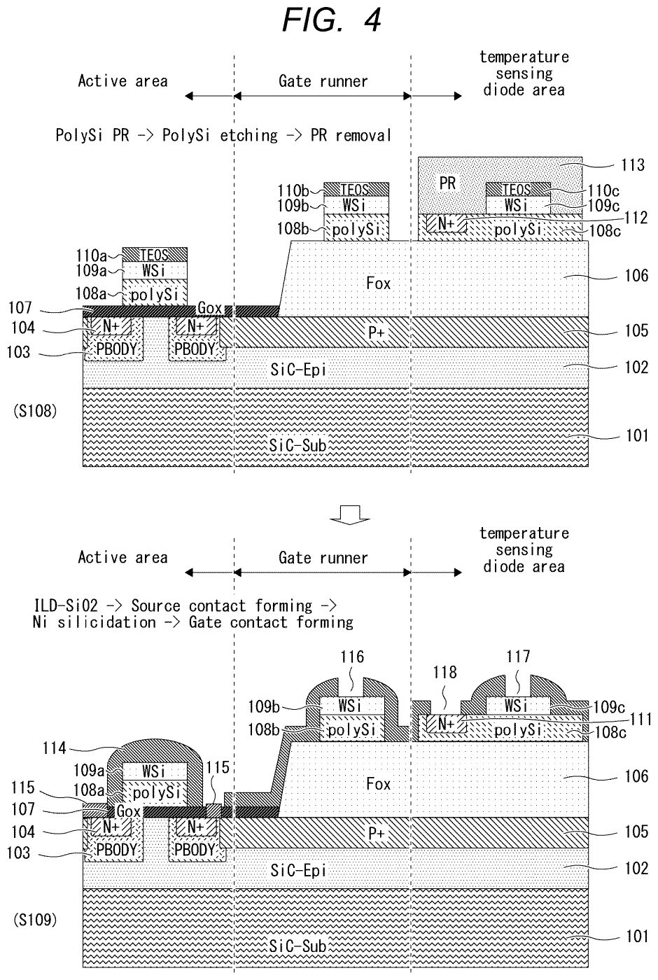

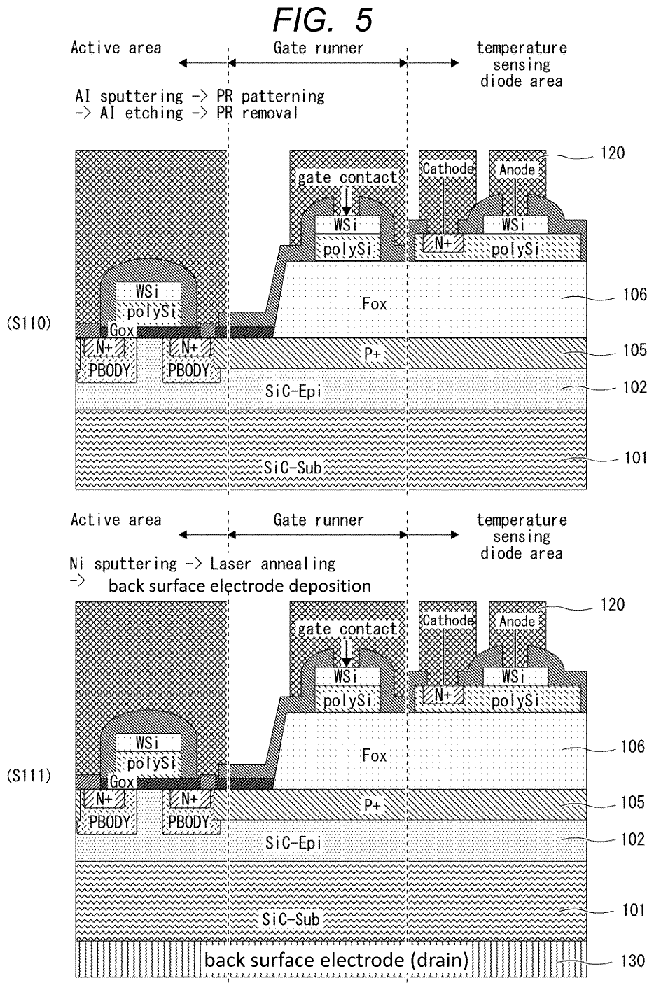

FIG. 1 to FIG. 5 are schematic cross-sectional views showing an example of each manufacturing step for explaining a manufacturing method of the semiconductor device 1 on which the temperature detection diode is mounted. The semiconductor device 1 is, for example, a power device mounted on a vehicle, and includes at least a plurality of MOSFETs 10 used as switching devices, a gate runner 30 that transmits a gate voltage to gate electrodes of the plurality of MOSFETs 10, and a temperature detection diode 20. The respective MOSFETs 10 are planar MOSFETs using SiC (silicon carbide). In FIG. 1 to FIG. 5, one of a plurality of MOSFETs 10 is shown. The temperature sensing diode 20 is formed adjacent to (or close to) MOSFET 10 and detects at least the temperature of MOSFET 10.

Here, the temperature detection diode 20 can be formed together with MOSFET 10 with a small number of masking processes, so that the manufacturing process of the semiconductor device 1 according to the present embodiment can be cost-reduced. Hereinafter, it will be described in detail.

The processes of the steps S101 to S104 are basically the same as the processes of the steps S501 to S504.

First, in the step S101 process, an epitaxial layer (Sic-Epi) 102 is formed on SiC-Sub 101 of SiC. The thickness of the substrate 101 is, for example, about 350 um. An N-type impurity is introduced into the substrate 101 at a relatively high concentration, and the N-type impurity is, for example, nitrogen (N). The resistivity of the substrate 101 is, for example, about 20 mΩcm. The thickness of the epitaxial layer 102 is, for example, about 5 to 50 umt. The epitaxial layer 102 contains N-type impurity, and the N-type impurity has approximately 1E15 to 5E16/cm\hat{ }3.

Thereafter, in the process of the step S102, an impurity layer is formed in the epitaxial layer 102. Specifically, by repeating photolithography (patterning of photoresist), ion-implantation, and photoresist-removal a plurality of times, a set of two PBODYs (P-type layers) 103, a set of two N+ diffusion regions 104, and P+ diffusion region 105 are formed from the surface of the N-type epitaxial layer 102 to the inside. As the P-type ions, for example, ions of Al (aluminum) are used, and as the N-type ions, for example, ions of N (nitrogen) are used. PBODYs 103 and N+ diffused regions 104 are formed in the active region, which is a region where MOSFETs 10 are formed. The P+ diffusion region 105 is formed in the formation region of the temperature detection diode 20 and the formation region of the gate runner 30 provided between the active region and the formation region of the temperature detection diode 20.

As a process between the process of step S101 and the process of step S102, an alignment mark for photolithography may be formed on the surface of the epitaxial layer 102.

Further, in the process of step S102, at least one of SiO2 and polysilicon may be deposited on the epitaxial layer 102 prior to photolithography, and then photolithography may be performed. In this case, etching using a patterned photoresist as a mask is performed to form a hard mask made of at least one of patterned SiO2 and polysilicon. Thereafter, ion-implantation is performed using at least one of the patterned SiO2 and polysilicon as a hard mask. At this time, the ion implantation may be performed at a high temperature of 300 to 600° C.

Further, in the process of the step S102, a P-type layer having a higher concentration than PBODY 103 and a lower concentration than the P+ diffusion regions 105 may be formed below PBODY 103 in the epitaxial layer 102.

Thereafter, in the process of the step S103, the impurity formed in the epitaxial layer 102 is activated. Specifically, the surface of the epitaxial layer 102 is annealed at 1600 to 1800° C. for 1 to 60 minutes. Before annealing, a carbon film may be deposited on the wafer surface (the surface of the epitaxial layer 102) or on both surfaces (the surface of the epitaxial layer 102 and the back surface of the substrate 101), and then annealing may be performed. In this case, the carbon film is removed after annealing. In this material, SiC wafer is annealed at a higher temperature than the melting point of Si system compared to Si wafer. Therefore, SiC wafer needs to be annealed prior to depositing Si based materials such as the field-oxide film, the gate-oxide film, and the polysilicon layer, which will be described later.

Thereafter, in the step S104 process, a field-oxide film (Fox), a gate-oxide film (Gox), and a polysilicon-layer (PolySi) are formed. Specifically, first, the field oxide film 106 is formed in the gate runner formation region and the temperature detection diode formation region (that is, in a region other than the active region). Thereafter, the gate oxide film 107 is formed in the active region by photolithography, oxide film etching, and gate oxidation. Thereafter, a non-doped polysilicon layer 108 is formed (deposited) on the respective surfaces of the field oxide film 106 and the gate oxide film 107.

Here, in the case where the temperature detection diode 20 is formed, the thickness of the polysilicon layer 108 is preferable larger than that in the case where the temperature detection diode 20 is not formed. For example, when the temperature detection diode 20 is not formed, the thickness of the polysilicon layer 108 is about 200 nm, whereas when the temperature detection diode 20 is formed, the thickness of the polysilicon layer 108 is preferable about 300 nm. This is in consideration of overetching of the polysilicon layer 108 in a subsequent step.

Note that thermal oxidation may be performed before the field oxide film 106 is formed. In addition, in the gate oxidation, sacrificial oxidation and removal thereof may be performed. Before and after the gate oxidation, a process of modifying MOS interface (e.g., NO annealing) may be performed.

Thereafter, in the process of the step S105, the polysilicon layer 108 is ion-implanted. Specifically, B (boron) having a dose 5E14/cm\hat{ }2 is implanted into the polysilicon layer 108 at 10 keV energies. As a result, the polysilicon layer 108 is made P-type.

Thereafter, in the process of the step S106, a WSi (tungsten silicide) layer and a TEOS (tetraethoxysilane) layer are formed and patterned on the polysilicon layer 108. Specifically, first, a WSi layer 109 and a TEOS layer 110 are sequentially deposited on the surface of the polysilicon layer 108, and then photolithography (patterning of a photoresist) is performed on the surface of TEOS layer 110. Thereafter, TEOS layer 110 and WSi layer 109 are etched using the patterned photoresist as a mask. After etching, the photoresist is removed. Note that the photoresist may be removed after etching TEOS layer 110 using the patterned photoresist as a mask and prior to etching WSi layer 109. In this process, WSi layer 109 is etched using the patterned TEOS layer 110 as a hard mask, and then the photoresist is removed. At this time, the polysilicon layer 108 is not etched.

Thus, in the active region of the polysilicon layer 108, a stacked region (first stacked region) composed of WSi layer 109a and TEOS layer 110a is formed in the active region, a stacked region (third stacked region) composed of WSi layer 109b and TEOS layer 110b is formed in the gate runner forming region, and a stacked region (second stacked region) composed of WSi layer 109c and TEOS layer 110c is formed in the temperature detection diode forming region. The first stacked region corresponds to the gate of MOSFET 10. The second stacked region corresponds to the anode of the temperature detection diode 20. The third stacked region corresponds to the gate of the gate runner 30. Each thickness of WSi layers 109a to 109c is, for example, about 250 nm. Each thickness of TEOS layers 110a to 110c is, for example, about 200 nm.

Here, when WSi layer 109 is etched, a portion of the polysilicon layer 108 may also be etched (i.e., overetched). Therefore, as described above, the thicker polysilicon layer 108 is formed in consideration of the overetching of the polysilicon layer 108 at this time.

Thereafter, in the process of the step S107, the N+ diffused region is formed in a part of the polysilicon layer 108. Specifically, first, photolithography (first mask processing) is performed so that a cathode formation region of the temperature detection diode 20 is exposed on the surface of the polysilicon layer 108. Thereafter, As (arsenic) is ion-implanted into the polysilicon layer 108 using the patterned photoresist 111 as a mask. For example, As having a dose 5E15/cm\hat{ }2 is implanted into the polysilicon layer 108 at 80 keV energies. As a result, the N+ diffusion region 112 is formed in the cathode formation region of the temperature detection diode 20 in the polysilicon layer 108. After ion implantation, the photoresist 111 is removed. Note that P (phosphorus) may be used instead of As to form the N+ diffused region 112.

Thereafter, in the step S108 process, the polysilicon layer 108 is patterned. Specifically, first, photolithography (second mask processing) is performed so that a region of the surface of the polysilicon layer 108 other than the temperature detection diode formation region is exposed. Thereafter, the polysilicon layer 108 is etched using the patterned photoresist 113 and TEOS layers 110a, 110b. As a result, the polysilicon layers 108a to 108c in the TEOS layer 110a forming region in the active region, TEOS layer 110b forming region in the gate runner forming region, and the diode formation region remain. After etching, the photoresist 113 is removed.

Thereafter, in the process of the step S109, an interlayer insulating film of SiO2 is formed, a source contact is formed, and a gate contact is formed. Specifically, first, the interlayer insulating film 114 of SiO2 is formed so as to cover the wafer. Since TEOS layer 110 (110a to 110c) is included in the interlayer insulating film 114, it is omitted. Thereafter, in the active region, the contact hole 115 is formed on the upper surface of the N+ diffusion region 104 and so as to separate the stacked region of the polysilicon 108a and WSi layer 109a from the interlayer insulating film 114. A Ni silicide is formed in the contact hole 115. For example, in forming Ni silicide, first annealing is performed on Ni (nickel) formed in the contact hole 115, and then second annealing is performed after the unreacted part of the annealing is removed. In addition, a contact hole 116 is formed in the gate runner formation region, and a contact hole 117 is formed in the temperature detection diode formation region. Although not shown, a contact hole corresponding to the gate of MOSFET 10 may be formed. The contact hole 116 is formed in a region corresponding to the gate of the gate runner 30, but since the gate voltage of the gate runner 30 is supplied to the gate of MOSFET 10, the contact hole 116 may be formed in a region corresponding to the gate of MOSFET 10.

For example, the contact hole 116 is formed on the upper surface of the stacked region of the polysilicon layer 108b and WSi layer 109b in the interlayer insulating film 114. The upper surface of the stacked region of the polysilicon layer 108b and WSi layer 109b is used as a gate contact of the gate runner 30. In the interlayer insulating film 114, contact hole 117 is formed on the upper surface of the polysilicon layer 108c and WSi layer 109c. The upper surface of the polysilicon layer 108c and WSi layer 109c is used as an anode of the temperature detection diode 20. Further, in the interlayer insulating film 114, a contact hole 118 is formed on the upper surface of the N+ diffusion region 112. The upper surface of the N+ diffusion region 112 is used as a cathode of the temperature detection diode 20. Although not shown, a contact hole may be formed in the upper surface of the stacked region of the polysilicon layer 108a and WSi layer 109a in the interlayer insulating film 114. The upper surface of the stacked region of the polysilicon layer 108a and WSi layer 109a is used as the gate contact of MOSFET 10.

First, the P-type polysilicon layer is used as the gate electrode of MOSFET 10, so that the threshold voltage can be increased by about 1 V, which is the band gap of Si (silicon). In addition, by depositing WSi layer on the P-type polysilicon layer and using it as the gate electrode of MOSFET 10 and the gate runner 30, the gate wiring resistance can be reduced. The lower the gate wiring resistance, the faster the switching speed of the MOSFET 10, and therefore the energy loss during switching is suppressed.

Thereafter, although not shown, a TiW (titanium-tungsten) is deposited over the substrate (wafer), and the deposited TiW is annealed. As a result, a layer of annealed (i.e., silicided) TiW is formed on the upper surface of the N+ diffused region 112. Note that TiW is not limited to being deposited on the substrate (wafer), and Ti (titanium) and TiN (titanium nitride) may be stacked, or Ti and TiW may be stacked. Here, the stacked Ti, TiN or the stacked Ti, TiW is annealed.

Then, in the step S110 process, the surface electrode is formed. Specifically, first, Al is sputtered on the front face of the substrate. Then, photolithography is performed on the deposited Al layer 120. Thereafter, the deposited Al layer 120 and TiW are etched using the patterned photoresist as a mask. As a result, the source electrode of MOSFET 10, the gate electrode of MOSFET 10 (not shown), the gate electrode of the gate runner 30, the anode electrode of the temperature detection diode 20, and the cathode electrode are respectively formed. After etching, the photoresist is removed.

After that, in the process of the step S111, the back surface electrode is formed. Specifically, first, Ni is sputtered on the back surface of the substrate. Thereafter, laser annealing is performed on the deposited Ni layer to form Ni silicide. As a result, the back surface electrode 130 is formed on the back surface of the substrate.

Note that the back surface of the substrate 101 may be ground and thinned before the back surface electrode 130 is formed. In addition, the back surface 130 is not limited to being formed by Ni silicide, and may be formed by a stacked Ti, Ni, Ag, Au.

As described above, the temperature detection diode 20 can be formed together with MOSFET 10 with a small number of masking processes.

Although the invention made by the present inventors has been specifically described based on the embodiments, the present invention is not limited to the above-described embodiments, and it is needless to say that various modifications can be made without departing from the gist thereof.

What is claimed is:

1. A method of manufacturing a semiconductor device, the method comprising:
forming a p-type polysilicon layer on an SiC substrate on which an impurity layer is formed;
stacking a WSi layer and a TEOS layer on the polysilicon layer;
patterning the stacked WSi layer and TEOS layer so as to leave at least a first stacked region corresponding to a gate of MOSFET and a second stacked region corresponding to an anode of a temperature detection diode;
performing a first mask process so that, on a surface of the p-type polysilicon layer, a first region corresponding to a cathode of the temperature detection diode is exposed;
implanting n-type ions into the first region;
performing a second mask process so that, on the surface of the p-type polysilicon layer, a formation region of the temperature detection diode is masked;
performing etching on an exposed region of the p-type polysilicon layer;
forming an interlayer insulating layer over the SiC substrate; and
forming a contact hole in each of a region corresponding to a source of the MOSFET, a region corresponding to the gate of the MOSFET, a region corresponding to the anode of the temperature detection diode and a region corresponding to the cathode of the temperature detection diode.

2. The method of manufacturing the semiconductor device according to claim 1, wherein arsenic ions are implanted into the first region as the n-type ions.

3. The method of manufacturing the semiconductor device according to claim 1, wherein the p-type polysilicon layer is formed by implanting boron ions into a non-doped polysilicon layer.

4. The method of manufacturing the semiconductor device according to claim 1, further comprising:
forming the p-type impurity layer by implanting aluminum ions into the SiC substrate, and forming the n-type impurity layer by implanting nitrogen ions into the p-type polysilicon layer prior to the forming of the p-type polysilicon layer,
wherein the p-type polysilicon layer is formed by implanting boron ions into a non-doped polysilicon layer, and
wherein arsenic ions are implanted into the first region as the n-type ions.

5. The method of manufacturing the semiconductor device according to claim 1, further comprising:
annealing the SiC substrate on which the impurity layer is formed prior to the forming of the polysilicon layer.

6. The method of manufacturing the semiconductor device according to claim 1, wherein the MOSFET is a planar MOSFET.

7. The method of manufacturing the semiconductor device according to claim 1, further comprising:
forming a TiW layer on the first region corresponding to the cathode of the temperature detection diode; and
annealing the TiW layer formed on the first region.

8. The method of manufacturing the semiconductor device according to claim 1, further comprising:
stacking a Ti layer and a TiN layer on top of the first region corresponding to the cathode of the temperature detection diode; and
annealing the Ti layer and the TiN layer stacked on the first region.

9. The method of manufacturing the semiconductor device according to claim 1, further comprising:
Stacking a Ti layer and a TiW layer on top of the first region corresponding to the cathode of the temperature detection diode; and
annealing the Ti layer and the TiW layer stacked on the first region.

10. A semiconductor device comprising:
an SiC substrate on which an impurity layer is formed;
a first stacked portion comprising a p-type first polysilicon layer and a first WSi layer which are stacked on the SiC substrate, the first stacked portion being used for a gate of MOSFET;
a second stacked portion comprising a p-type second polysilicon layer and a second WSi layer which are stacked on the SiC substrate, the second stacked portion being used for an anode of a temperature detection diode;
a contact layer provided on the SiC substrate and corresponding to the first stacked portion, the contact layer being used for a source of the MOSFET;
an n-type diffusion region formed in the second polysilicon layer, the n-type diffusion region being used for a cathode of the temperature detection diode.

11. The semiconductor device according to claim 10, further comprising:
one of a TiW layer, a stacked Ti layer and TiN layer, and a stacked Ti layer and TiW layer formed on the surface of the n-type diffusion region.
